(19) United States
(12) Patent Application Publication
(10) Pub. No.: US 2025/0022629 A1
(43) Pub. Date: Jan. 16, 2025

(54) CONDUCTIVE FILM AND DISPLAY DEVICE

(71) Applicant: TDK Corporation, Tokyo (JP)

(72) Inventors: Hiroshi SHINGAI, Tokyo (JP); Keisuke NISHIOKA, Tokyo (JP); Haruna OGAWA, Tokyo (JP); Shinsuke HASHIMOTO, Tokyo (JP)

(73) Assignee: TDK Corporation, Tokyo (JP)

(21) Appl. No.: 18/897,309

(22) Filed: Sep. 26, 2024

Related U.S. Application Data
(63) Continuation of application No. PCT/JP2023/008405, filed on Mar. 6, 2023.

(30) Foreign Application Priority Data
Mar. 29, 2022 (JP) 2022-053995

(51) Int. Cl. H01B 1/22; H01B 17/64

(52) U.S. Cl. CPC H01B 1/22; H01B 17/64

(57) ABSTRACT

A conductive film includes a base material 1, a first resin layer 10 provided on the base material 1, a second resin layer 20 provided on the first resin layer 10 and having a trench 25 opening to a surface opposite to the first resin layer 10, and a conductive layer 30 provided in the trench 25. The first resin layer 10 contains a first resin portion 12 and a plurality of first inorganic particles 11. At least a part of the plurality of first inorganic particles 11 partially protrude from the first resin portion 12 toward the second resin layer 20.

### CROSS-REFERENCE TO RELATED APPLICATIONS

This application is a continuation application of PCT Application No. PCT/JP2023/008405, filed on Mar. 6, 2023, which claims the benefit of priority based on Japanese Patent Application No. 2022-053995 filed on Mar. 29, 2022, and the entire contents of each are incorporated herein by reference.

### TECHNICAL FIELD

The present disclosure relates to a conductive film and a display device.

### BACKGROUND ART

A transparent antenna having a conductive substrate (conductive film) that is transparent and conductive is sometimes mounted on a surface of a touch panel or a display. Recently, as touch panels and displays have become larger and more diverse, conductive films are required to have flexibility as well as high transparency and conductivity.

As a method of manufacturing the conductive substrate, for example, Patent Literature 1 discloses a method including the steps of forming a trench in a trench forming layer, formed on an underlayer formed on a base material, to expose the underlayer and growing a metal plating from the underlayer exposed in the trench to form a conductive pattern layer that fills the trench.

### CITATION LIST

### Patent Literature

[Patent Literature 1] Japanese Patent Application Laid-Open No. 2019-29658

### SUMMARY

An aspect of the present disclosure relates to a conductive film including a base material, a first resin layer provided on the base material, a second resin layer provided on the first resin layer and having a trench opening to a surface opposite to the first resin layer, and a conductive layer provided on the trench. The first resin layer contains a first resin portion and a plurality of first inorganic particles. At least a part of the plurality of first inorganic particles partially protrude from the first resin portion toward the second resin layer.

Another aspect of the present disclosure relates to a display device including the conductive film.

### BRIEF DESCRIPTION OF DRAWINGS

FIG. 1 is a schematic plan view showing a conductive film according to an embodiment.

FIG. 2 is a cross-sectional view taken along a line II-II of FIG. 1.

FIG. 3 is a partially enlarged view of the conductive film shown in FIG. 2.

FIG. 4A is a cross-sectional view schematically showing a method for manufacturing the conductive film shown in FIG. 1.

FIG. 4B is a cross-sectional view schematically showing a method for manufacturing the conductive film shown in FIG. 1.

FIG. 4C is a cross-sectional view schematically showing a method for manufacturing the conductive film shown in FIG. 1.

FIG. 4D is a cross-sectional view schematically showing a method for manufacturing the conductive film shown in FIG. 1.

FIG. 5A is a cross-sectional view schematically showing a method for manufacturing the conductive film shown in FIG. 1.

FIG. 5B is a cross-sectional view schematically showing a method for manufacturing the conductive film shown in FIG. 1.

FIG. 5C is a cross-sectional view schematically showing a method for manufacturing the conductive film shown in FIG. 1.

FIG. 6 is a cross-sectional view showing an embodiment of a display device.

### DESCRIPTION OF EMBODIMENTS

### Problem to be Solved by the Present Disclosure

For conductive films having a second resin layer forming trenches filled with a conductive layer on a first resin layer, it is desirable to have high adhesion between the first and second resin layers.

### Effect of the Present Disclosure

A conductive film having high adhesion between a first resin layer and a second resin layer and a display device using this conductive film are provided.

The present disclosure is not limited to the following examples.

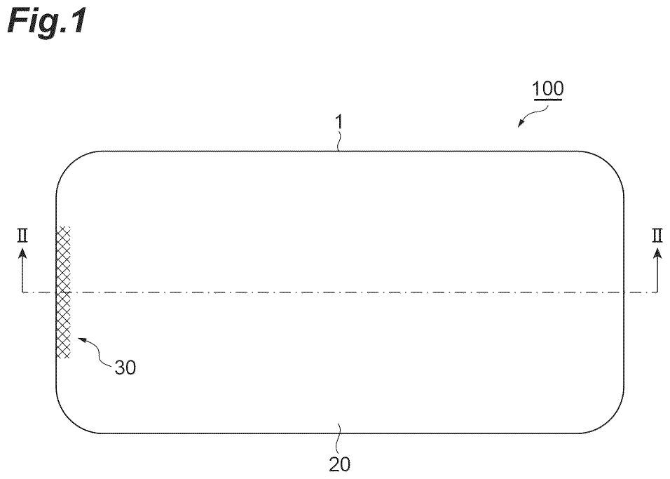

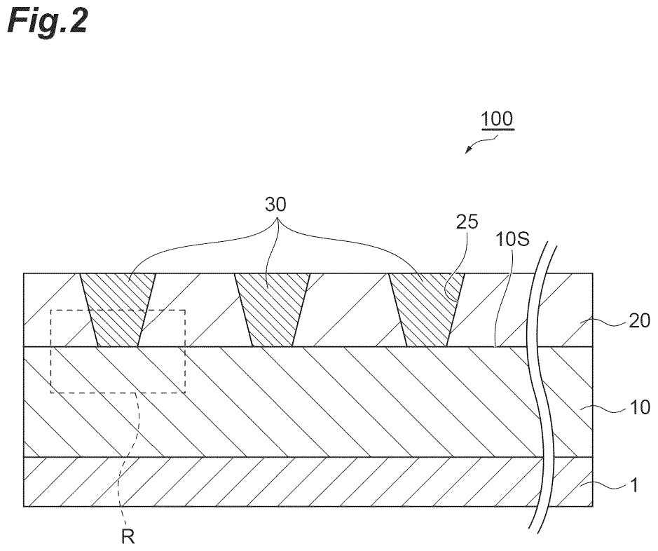

FIG. 1 is a schematic plan view showing a conductive film according to an embodiment. FIG. 2 is a cross-sectional view taken along a line II-II of FIG. 1. A conductive film 100 shown in FIGS. 1 and 2 includes a film-like base material 1, a first resin layer 10 which is provided on the base material 1, a second resin layer 20 which is provided on the first resin layer 10 and has a linear trench 25 opening to a surface opposite to the first resin layer 10, and a conductive layer 30 which is provided on the trench 25. In FIGS. 1 and 2, a mesh-like pattern is formed by a plurality of the linear trenches 25 extending in each of the two directions intersecting with each other. The conductive layer 30 in the trench 25 also forms a mesh-like pattern. The conductive layer 30 having a mesh-like pattern can function well as, for example, a radiating element of an antenna. The trench 25 and the conductive layer 30 are provided over a partial region of a surface 10S of the first resin layer 10.

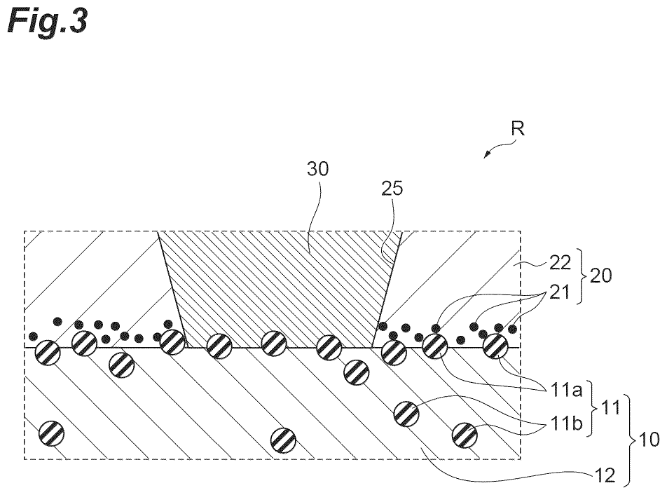

FIG. 3 is an enlarged view of a region R in the cross-sectional view of the conductive film 100 shown in FIG. 2. As shown in FIG. 3, the first resin layer 10 contains a first resin portion 12 and a plurality of first inorganic particles 11, and the second resin layer 20 contains a second resin portion 22 and a plurality of second inorganic particles 21.

The base material 1 may be a transparent base material and particularly may be a transparent resin film. The resin film may be, for example, a film of polyethylene terephthalate (PET), polycarbonate (PC), polyethylene naphthalate (PEN), cycloolefin polymer (COP), or polyimide (PI). The base material 1 may be glass, a Si wafer, or the like. The base material 1 may have a degree of light transparency required when the conductive film 100 is incorporated into a display device, for example. Specifically, the total light transmittance of the base material may be 90 to 100%, and the haze of the base material may be 0 to 5%.

The thickness of the base material 1 may be 10 μm or more, 20 μm or more, or 35 μm or more and may be 500 μm or less, 200 μm or less, or 100 μm or less.

The first resin portion 12 constituting the first resin layer 10 may be a cured product of a curable resin composition containing a curable resin. The first resin layer 10 may be transparent. Examples of curable resins include amino resins, cyanate resins, isocyanate resins, polyimide resins, epoxy resins, oxetane resins, polyesters, allyl resins, phenolic resins, benzoxazine resins, xylene resins, ketone resins, furan resins, COPNA resins, silicon resins, dicyclopentadiene resins, benzocyclobutene resins, episulfide resins, ene-thiol resins, polyazomethine resins, polyvinyl benzyl ether compounds, acenaphthylene, and ultraviolet-curable resins containing functional groups that undergo polymerization reactions when exposed to ultraviolet light, such as unsaturated double bonds, cyclic ethers, and vinyl ethers. The curable resin may be one type alone or a combination of two or more types.

The first inorganic particles 11 are dispersed in the first resin portion 12. Examples of the first inorganic particles 11 include silica, alumina, titania, tantalum oxide, zirconia, silicon nitride, barium titanate, barium carbonate, magnesium carbonate, aluminum hydroxide, magnesium hydroxide, lead titanate, lead zirconate titanate, lead lanthanum zirconate titanate, gallium oxide, spinel, mullite, cordierite, talc, aluminum titanate, barium silicate, boron nitride, calcium carbonate, barium sulfate, calcium sulfate, zinc oxide, magnesium titanate, hydrotalcite, mica, calcined kaolin, and carbon. The first inorganic particles 11 may be one type alone or a combination of two or more types.

The shape of the first inorganic particles 11 is not particularly limited, and may be, for example, spherical, ellipsoidal, polyhedral, plate-like, scaly, columnar, or the like.

At least a part of a plurality of the first inorganic particles 11 partially protrudes from the first resin portion 12 toward the side of the second resin layer 20. The “state in which the first inorganic particles 11 partially protrude from the first resin portion 12 toward the side of the second resin layer 20” means a state in which a part of the surface of the first inorganic particles 11 protrudes from the first resin portion 12 toward the side of the second resin layer 20 and is in contact with the second resin layer 20. That is, a plurality of the first inorganic particles 11 that partially protrude toward the side of the second resin layer 20 are in a state in which the portions protruding toward the side of the second resin layer 20 are not covered by the first resin portion 12 (the portions protruding toward the side of the second resin layer 20 are exposed from the first resin portion 12). Hereinafter, such first inorganic particles are also referred to as “exposed first inorganic particles”. The exposed first inorganic particles 11a can contribute to improving the adhesion between the first resin layer 10 and the second resin layer 20. The presence of the exposed first inorganic particles 11a can be confirmed, for example, by observing a cross section of the conductive film 100 along the thickness direction with a TEM (Transmission Electron Microscope). The first inorganic particles 11 may contain first inorganic particles 11b that are embedded in the first resin portion 12 and do not protrude toward the side of the second resin layer 20 (are not exposed from the first resin portion 12).

From the viewpoint of excellent adhesion between the first resin layer 10 and the second resin layer 20 of the conductive film 100, the ratio of the number of the exposed first inorganic particles 11a to the total number of the first inorganic particles 11 may be 10% or more. The ratio of the number of the exposed first inorganic particles 11a to the total number of first inorganic particles 11 may be, for example, 40% or less. The ratio of the number of the exposed first inorganic particles 11a is calculated by observing a cross section of the conductive film 100 along the thickness direction with a TEM and measuring the number of the exposed first inorganic particles 11a in a cross-sectional image of the first resin layer 10 within a range of 1.5 μm in any extending direction of the conductive film 100 and the number of all first inorganic particles 11 in a cross-sectional image of the first resin layer 10 within the same range.

A plurality of the first inorganic particles 11 may be unevenly distributed on the side of the second resin layer 20 in the first resin layer 10. The fact that a plurality of the first inorganic particles 11 are unevenly distributed on the side of the second resin layer 20 in the first resin layer 10 can be confirmed by observing a cross section of the conductive film 100 along the thickness direction with a TEM.

The “state in which a plurality of the first inorganic particles 11 are unevenly distributed on the side of the second resin layer 20 in the first resin layer 10” means, for example, that the ratio of the number of first inorganic particles 11 (including exposed first inorganic particles 11a) present in a region A exceeds 50% of the total number of the first inorganic particles 11 in the entire first resin layer 10 when a region on the side of the second resin layer 20 from the center of the first resin layer 10 in the thickness direction in a cross section of the conductive film 100 along the thickness direction is the region A. This ratio may be 60% or more, 70% or more, 75% or more, or 80% or more.

The average particle diameter of the first inorganic particles 11 may be, for example, 10 nm or more, 15 nm or more, or 20 nm or more and may be 400 nm or less, 300 nm or less, or 200 nm or less. The average particle diameter of the first inorganic particles 11 is calculated by observing a cross section of the conductive film 100 along the thickness direction with a TEM, measuring a maximum length of each of the first inorganic particles 11 present within a range of 1.5 μm in any extending direction of the conductive film 100 in a TEM image of the cross section, and averaging the maximum lengths.

The thickness of the first resin layer 10 or the first resin portion 12 may be, for example, 30 nm or more, 50 nm or more, or 100 nm or more and may be 500 nm or less, 400 nm or less, or 300 nm or less.

The second resin layer 20 is a resin layer mainly composed of a second resin portion 22. The second resin portion 22 may be transparent. The second resin portion 22 may be a cured product of a photocurable resin or a thermosetting resin. Examples of photocurable resins or thermosetting resins include acrylic resins, amino resins, cyanate resins, isocyanate resins, polyimide resins, epoxy resins, oxetane resins, polyesters, allyl resins, phenolic resins, benzoxazine resins, xylene resins, ketone resins, furan resins, COPNA resins, silicon resins, dicyclopentadiene resins, benzocyclobutene resins, episulfide resins, ene-thiol resins, polyazomethine resins, polyvinylbenzyl ether compounds, acenaphthylene, ultraviolet-curable resins containing functional groups that undergo polymerization reactions when exposed to ultraviolet light, such as unsaturated double bonds, cyclic ethers, and vinyl ethers. These photocurable resins or thermosetting resins may be one type alone or a combination of two or more types.

The second resin layer 20 may contain second inorganic particles 21. The second inorganic particles 21 may be one or more type of inorganic particles selected from Pd, Cu, Ni, Co, Au, Ag, Pd, Rh, Pt, In, and Sn, and may contain Pd. The second inorganic particles 21 may be one type alone or a combination of two or more types of inorganic particles.

The shape of the second inorganic particles 21 is not particularly limited, and may be, for example, spherical, ellipsoidal, polyhedral, plate-like, scaly, columnar, or the like.

From the viewpoint of excellent transparency of the conductive film 100, the average particle diameter of the second inorganic particles 21 may be 10 nm or less, 8 nm or less, or 5 nm or less. The average particle diameter of the second inorganic particles 21 may be, for example, 0.1 nm or more, 0.5 nm or more, or 1 nm or more. The average particle diameter of the second inorganic particles 21 is calculated by observing a cross section of the conductive film 100 along the thickness direction with a TEM, measuring a maximum length of each of the second inorganic particles 21 present within a range of 1.5 μm in any extending direction of the conductive film 100 in a TEM image of the cross section, and averaging the maximum lengths.

The average particle diameter of the second inorganic particles 21 may be smaller than the average particle diameter of the first inorganic particles 11. The ratio of the average particle diameter of the second inorganic particles 21 to the average particle diameter of the first inorganic particles 11 (the average particle diameter of the second inorganic particles 21/the average particle diameter of the first inorganic particles 11) may be 0.3 or less, or 0.1 or less and may be 0.01 or more, 0.02 or more, or 0.05 or more.

A plurality of the second inorganic particles 21 may be unevenly distributed on the side of the first resin layer 10 in the second resin layer 20. The “state in which a plurality of the second inorganic particles 21 are unevenly distributed on the side of the first resin layer 10 in the second resin layer 20” means, for example, that the ratio of the number of the second inorganic particles 21 in a region B exceeds 50% of the total number of the second inorganic particles 21 in the entire second resin layer 20 when a region on the side of the first resin layer 10 from the center of the second resin layer 20 in the thickness direction in a cross section of the conductive film 100 along the thickness direction is the region B. This ratio may be 80% or more, 90% or more, or 95% or more.

From the viewpoint of excellent transparency of the conductive film 100, the second inorganic particles 21, which correspond to 80% or more of the total number of the second inorganic particles 21, may be distributed within a region whose distance from the interface between the first resin layer 10 and the second resin layer 20 is ⅓ or less, ¼ or less, or ⅕ or less of the thickness of the first resin layer 10. The second inorganic particles 21, which correspond to 90% or more or 95% or more of the total number of the second inorganic particles 21, may be distributed within a region whose distance from the interface between the first resin layer 10 and the second resin layer 20 is ⅓ or less, ¼ or less, or ⅕ or less of the thickness of the first resin layer 10. The “interface between the first resin layer 10 and the second resin layer 20” means the interface between the first resin portion 12 and the second resin portion 22, and the interface between the exposed first inorganic particles 11a and the second resin portion 22.

From the viewpoint of excellent transparency of the conductive film 100, 80% or more of the second inorganic particles 21 relative to the total number of the second inorganic particles 21 may be distributed within a region whose distance from the surface of the first resin layer 10 (the surface of the first resin portion 12 or the surface of the exposed first inorganic particles 11a) is 70 nm or less, 65 nm or less, 60 nm or less, 55 nm or less, 50 nm or less, 45 nm or less, 40 nm or less, 35 nm or less, 30 nm or less, 25 nm or less, 20 nm or less, 15 nm or less, or 10 nm or less. 90% or more or 95% or more of the second inorganic particles 21 relative to the total number of the second inorganic particles 21 may be distributed within a region whose distance from the surface of the first resin layer 10 (the surface of the first resin portion 12 or the surface of the exposed first inorganic particles 11a) is 70 nm or less, 65 nm or less, 60 nm or less, 55 nm or less, 50 nm or less, 45 nm or less, 40 nm or less, 35 nm or less, 30 nm or less, 25 nm or less, 20 nm or less, 15 nm or less, or 10 nm or less.

A plurality of the second inorganic particles 21 may be present in the periphery of each of the plurality of exposed first inorganic particles 11a protruding (exposed) toward the side of the second resin layer 20. In this case, the adhesion between the first resin layer 10 and the second resin layer 20 can be further improved. The “periphery of the portion of each of the first inorganic particles 11a protruding toward the side of the second resin layer 20” may refer to a region within 10 nm from the surface of the portion of each of the first inorganic particles 11a protruding toward the side of the second resin layer 20. A portion of one exposed first inorganic particle 11a protruding toward the side of the second resin layer 20 may be in contact with a plurality of the second inorganic particles 21.

A plurality of the second inorganic particles may be present in the periphery of each of the plurality of exposed first inorganic particles 11a protruding (exposed) toward the side of the second resin layer 20. In this case, the adhesion between the first resin layer 10 and the second resin layer 20 can be further improved. The “periphery of the portion of each of the first inorganic particles 11a protruding toward the side of the second resin layer 20” may refer to a region within 10 nm from the surface of the portion of each of the first inorganic particles 11a protruding toward the side of the second resin layer 20. A portion of one exposed first inorganic particle 11a protruding toward the side of the second resin layer 20 may be in contact with a plurality of the second inorganic particles.

The trench 25 opens on the surface opposite to the first resin layer 10 and extends onto the second resin layer 20. The trench 25 contains a portion that forms a pattern corresponding to the pattern of the conductive layer 30. As shown in FIG. 2, the width of the trench 25 may become narrow from the second resin layer 20 opposite to the side of the first resin layer 10 toward the side of the first resin layer 10 and the width of the trench 25 may be substantially constant in the depth direction.

The width and depth of the trench 25 typically and substantially correspond to the width and thickness of the conductive layer 30, respectively. In this specification, the width of the trench 25 means the maximum width in a direction perpendicular to the thickness direction of the conductive film 100 (the extending direction of the conductive film 100), and the depth of the trench 25 means the maximum depth in the thickness direction of the conductive film 100. The ratio of the depth of the trench 25 to the width of the trench 25 may be similar to the aspect ratio of the conductive layer 30 described later.

The conductive layer 30 may be a layer formed of a single metal plating or may be formed of a plurality of metal platings of different metal species. The metal plating as the conductive layer 30 may contain, for example, at least one metal selected from copper, nickel, cobalt, palladium, silver, gold, platinum, and tin, and may also contain copper. The conductive layer 30 may further contain a nonmetallic element such as phosphorus as long as the conductive layer 30 maintains its conductivity.

When the conductive layer 30 includes a seed layer and an upper metal plating layer, the metal constituting the seed layer and the metal constituting the upper metal plating layer may be the same or different. For example, the seed layer may contain nickel and the upper metal plating layer may contain copper. The upper metal plating layer may be composed of a copper plating layer formed on the seed layer and a top layer containing gold or palladium formed on the copper plating layer.

The conductive layer 30 may have a pattern including linear portions. The pattern of the conductive layer 30 may contain a plurality of linear portions arranged while extending along a certain direction. The conductive layer 30 may have a mesh-like pattern including linear portions.

The width of the linear portion of the conductive layer 30 may be 1 μm or more, 10 μm or more, or 20 μm or more and may be 90 μm or less, 70 μm or less, or 30 μm or less. In this specification, the width of the linear portion of the conductive layer 30 refers to the maximum width in the extending direction of the conductive layer 30. From the viewpoint of improving the transparency of the conductive film 100, the width of the linear portion of the conductive layer 30 may be 0.3 μm or more, 0.5 μm or more, or 1.0 μm or more and may be 5.0 μm or less, 4.0 μm or less, or 3.0 μm or less.

The thickness of the conductive layer 30 may be 0.1 μm or more, 1.0 μm or more, or 2.0 μm or more and may be 10.0 μm or less, 5.0 μm or less, or 3.0 μm or less. The width and thickness of the linear portion of the conductive layer 30 can be adjusted by changing the design of a mold 50 described below and changing the width and thickness of the trenches 25.

The aspect ratio of the conductive layer 30 may be, for example, 0.1 or more, 0.5 or more, or 1.0 or more and may be 10.0 or less, 7.0 or less, or 4.0 or less. The aspect ratio of the conductive layer 30 refers to the ratio of the thickness of the conductive layer 30 to the width of the conductive layer 30 (thickness/width).

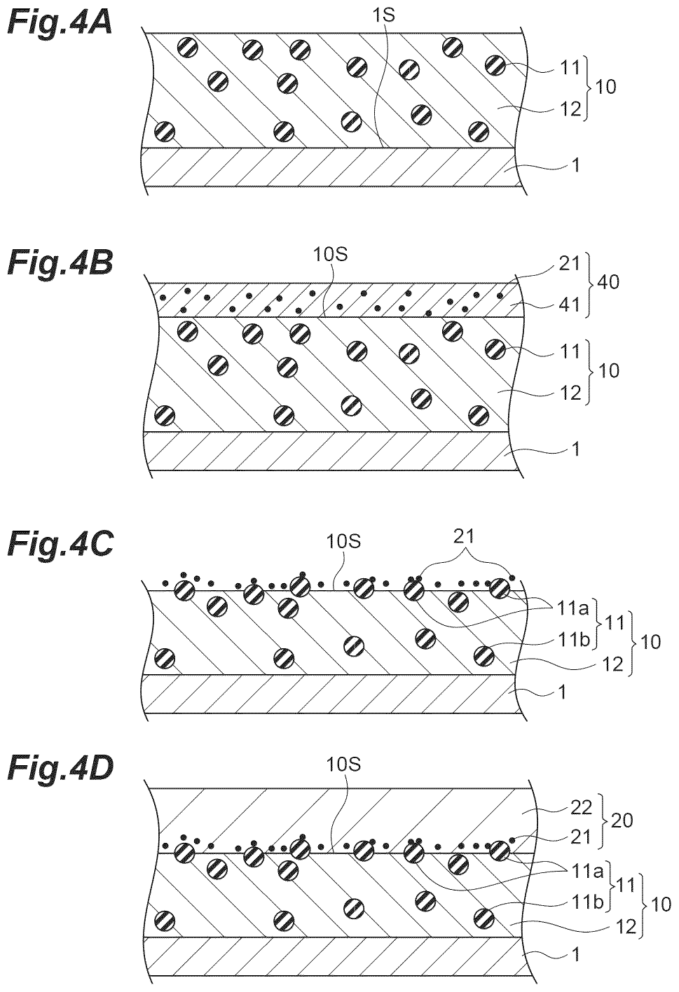

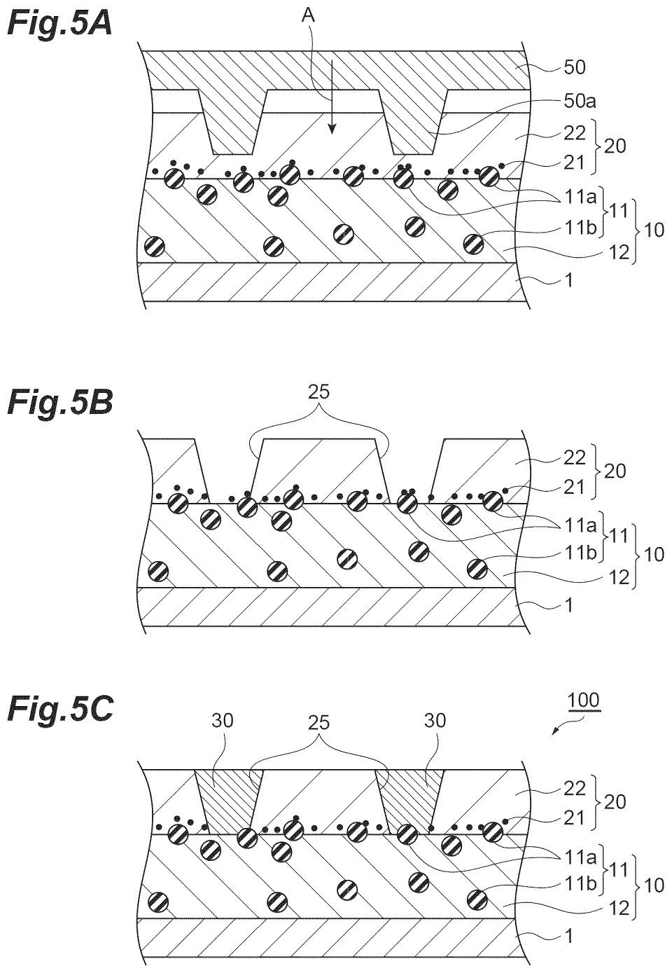

FIGS. 4A to 5C are cross-sectional views schematically showing an example of a method for manufacturing the conductive film 100 shown in FIG. 1. In the method according to this embodiment, first, as shown in FIG. 4A, the first resin layer 10 containing the first inorganic particles 11 is formed on one surface 1S of the film-like base material 1. The first resin layer 10 is formed, for example, by a method including applying a coating liquid containing a resin component forming the first resin portion 12, the first inorganic particles 11, and a solvent onto the base material 1, and removing the solvent from the coating on the base material 1. The step of FIG. 4A may be a step of preparing a laminate including the base material 1 and the first resin layer 10 formed on the base material 1.

As shown in FIG. 4B, a second inorganic particle containing layer 40 is formed on the surface 10S of the first resin layer 10 opposite to the base material 1. The second inorganic particle containing layer 40 is a layer containing second inorganic particles 21 and a third resin portion 41. The third resin portion 41 may be formed of the same material as the second resin portion 22. The step of FIG. 4B may be a step of preparing a laminate in which the base material 1, the first resin layer 10, and the second inorganic particle containing layer 40 are provided in this order.

As shown in FIG. 4C, the first inorganic particles 11 are exposed from the surface 10S of the first resin layer 10. As a method for exposing the first inorganic particles 11 from the surface 10S, for example, a method can be exemplified which performs an ashing process on the laminate of FIG. 4B to remove a part of the third resin portion 41 in the second inorganic particle containing layer 40 and the first resin portion 12 in the first resin layer 10. As a result of the ashing process, the first resin layer 10 becomes thinner than it was at the time of FIG. 4B. Although a part of the first resin portion 12 is removed by the ashing process, the first inorganic particles 11 present on the first resin portion 12 are not removed and remain on the first resin layer 10 opposite to the base material 1. Therefore, it is possible to form the first resin layer 10 in which the first inorganic particles 11 are unevenly distributed on the side opposite to the base material 1. The third resin portion 41 in the second inorganic particle containing layer 40 may be entirely removed by the ashing process or a part of the third resin portion 41 may remain on the surface 10S of the first resin layer 10. Since the third resin portion 41 in the second inorganic particle containing layer 40 is removed, the second inorganic particles 21 in the second inorganic particle containing layer 40 are deposited on the surface 10S of the first resin layer 10. The deposited second inorganic particles 21 may be attached to the first resin portion 12 or the exposed first inorganic particles 11a. The step of FIG. 4C may be a step of removing the first resin portion 12 in the first resin layer 10 and the third resin portion 41 in the second inorganic particle

As shown in FIG. 4D, the second resin layer 20 is formed on the surface 10S of the first resin layer 10. Specifically, a resin composition containing a resin component forming the second resin portion 22 is applied onto the surface 10S of the first resin layer 10 on which the second inorganic particles 21 are deposited, thereby forming the second resin layer 20 containing the second resin portion 22 and the second inorganic particles 21. Here, when a part of the third resin portion 41 in the second inorganic particle containing layer 40 remains on the surface 10S of the first resin layer 10, the remaining third resin portion 41 becomes a part of the second resin portion 22 in the second resin layer 20. The step of FIG. 4D may be a step of preparing a laminate in which the base material 1, the first resin layer 10, and the second resin layer 20 are provided in this order.

As shown in FIGS. 5A and 5B, the trench (groove portion) 25 is formed in the second resin layer 20 by an imprint method using the mold 50 having a convex portion 50a. In this step, the mold 50 with the convex portion 50a having a predetermined shape is moved in the direction indicated by arrow A to press it into the second resin layer 20 (FIG. 5A). The mold 50 may be pressed until the tip of the convex portion 50a reaches the first resin layer 10. In this state, the second resin portion 22 is cured as necessary. When the uncured second resin portion 22 contains a photocurable resin, the second resin portion 22 is cured by irradiating the second resin portion with light such as ultraviolet light. Then, the mold 50 is removed to form the trench 25 having a shape obtained by reversing the shape of the convex portion 50a of the mold 50 (FIG. 5B). The method for forming the trench 25 is not limited to the imprint method. For example, the trench 25 may be formed by a laser, dry etching, or photolithography. The trench 25 extends on the first resin layer 10 to form a pattern corresponding to the conductive layer 30. In order to expose the second inorganic particles 21 on the bottom surface of the trench 25, the second resin portion 22 remaining on the first resin layer 10 in the trench 25 may be removed by etching such as dry etching after removing the mold 50. The step of FIGS. 5A and 5B may be a step of forming the trench 25 that opens to the surface of the second resin layer 20 opposite the first resin layer 10 in the laminate in which the base material 1, the first resin layer 10, and the second resin layer 20 are provided in this order.

The mold 50 may be formed of quartz, Ni, ultraviolet curable liquid silicone rubber (PDMS), or the like. The shape of the convex portion 50a of the mold 50 is designed according to the shape of the trench 25 to be formed.

As shown in FIG. 5C, the conductive layer 30 is formed to fill the trench 25. The conductive layer 30 may be formed by an electroless plating method in which a metal plating is grown from the first resin layer 10. By immersing a laminate with the trench 25 in an electroless plating solution containing metal ions, metal plating can be grown from the bottom of the trench 25 to form the conductive layer 30. By forming the conductive layer 30 filling the trench 25, the conductive film 100 can be obtained.

The electroless plating solution contains ions of the metal that constitutes the conductive layer 30. The electroless plating solution may further contain phosphorus, boron, iron, and the like.

The temperature of the electroless plating solution when the laminate is immersed in the electroless plating solution may be, for example, 40 to 90° C. The immersion time in the electroless plating solution varies depending on factors such as the thickness of the conductive layer 30, but may be, for example, 10 to 30 minutes.

The conductive layer having the seed layer and the upper metal plating layer can be formed by a method including forming a seed layer (first metal layer) on the first resin layer 10 and forming an upper metal plating layer (second metal layer) on the seed layer. The laminate having the trench 25 is immersed in an electroless plating solution for forming a seed layer, thereby forming a metal plating as a seed layer on the first resin layer 10. Thereafter, the laminate having the seed layer is immersed in an electroless plating solution for forming an upper metal plating layer, thereby forming an upper metal plating layer on the seed layer. Before forming the upper metal plating layer, a catalyst may be adsorbed onto the seed layer, and the upper metal plating layer may be formed using the catalyst adsorbed onto the seed layer as a starting point.

The thickness of the seed layer may be 10 nm or more, 30 nm or more, or 50 nm or more, and may be 500 nm or less, 300 nm or less, or 100 nm or less.

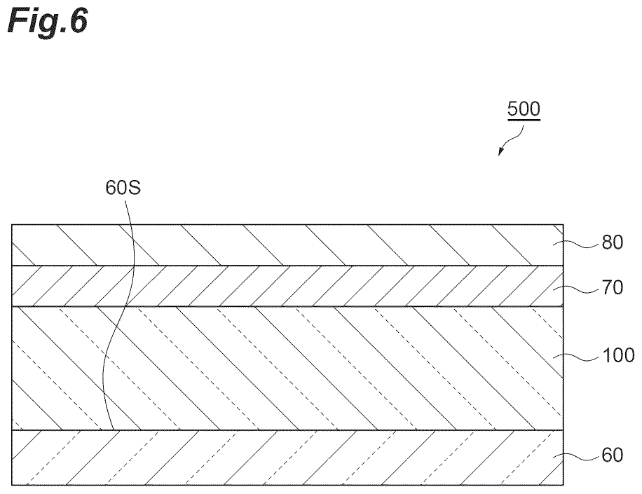

The conductive film described above can be incorporated into a display device as, for example, a planar transparent antenna. The display device may be, for example, a liquid crystal display device or an organic EL display device. FIG. 6 is a cross-sectional view showing an embodiment of a display device incorporating the conductive film 100. A display device 500 shown in FIG. 6 includes an image display unit 60 having an image display region 60S, the conductive film 100, a polarizing plate 70, and a cover glass 80. The conductive film 100, the polarizing plate 70, and the cover glass 80 are laminated in this order from the image display unit 60 on the side of the image display region 60S of the image display unit 60.

The configuration of the display device is not limited to the form shown in FIG. 6 and can be appropriately changed as necessary. For example, the polarizing plate 70 may be provided between the image display unit 60 and the conductive film 100. The image display unit 60 may be, for example, a liquid crystal display unit. The polarizing plate 70 and the cover glass 80 may be any of those commonly used in display devices. The polarizing plate 70 and the cover glass 80 may not be essentially provided.

Although a display device has been exemplified as a device to which the conductive film is applied, the conductive film may be applied to devices other than the display device. For example, a conductive film may be applied to the glass of a building, an automobile, and the like as a transparent antenna.

The technology according to the present disclosure includes the following configuration examples, but is not limited to these.

A conductive film according to an aspect of the present disclosure includes a base material, a first resin layer provided on the base material, a second resin layer provided on the first resin layer and having a trench opening to a surface opposite to the first resin layer, and a conductive layer provided in the trench, wherein the first resin layer contains a first resin portion and a plurality of first inorganic particles, and wherein at least a part of the plurality of first inorganic particles partially protrude from the first resin portion toward the second resin layer.

According to the conductive film, since at least a part of the plurality of first inorganic particles partially protrude from the first resin layer toward the second resin layer, the surface area of the first resin layer increases, and the adhesion between the first resin layer and the second resin layer is improved.

In the conductive film, the plurality of first inorganic particles may be unevenly distributed on the side of the second resin layer in the first resin layer. Therefore, since a large amount of the first inorganic particles are present on the side of the second resin layer in the first resin layer, the adhesion between the first resin layer and the second resin layer is further improved.

In the conductive film, the second resin layer may contain a second resin portion and a plurality of second inorganic particles, and the plurality of second inorganic particles may be unevenly distributed on the side of the first resin layer in the second resin layer. Therefore, since the second resin layer contains the plurality of second inorganic particles on the side of the first resin layer, the adhesion between the first resin layer and the second resin layer is further improved.

In the conductive film, a plurality of the second inorganic particles may be present around a portion protruding toward the second resin layer in each of the plurality of first inorganic particles partially protruding toward the second resin layer. Therefore, the adhesion between the first resin layer and the second resin layer is further improved.

In the conductive film, an average particle size of the plurality of second inorganic particles may be smaller than an average particle size of the plurality of first inorganic particles. Therefore, the adhesion between the first resin layer and the second resin layer is further improved and the transparency of the conductive film is improved by the first inorganic particles protruding from the first resin layer and the second inorganic particles contained in the second resin layer and smaller than the first inorganic particles.

In the conductive film, an average particle size of the plurality of second inorganic particles may be 10 nm or less. Therefore, the transparency of the conductive film is improved.

In the conductive film, the second inorganic particles which correspond to 80% or more of the total number of the plurality of second inorganic particles may be distributed within a region whose distance from a surface of the first resin layer is ⅓ or less of the thickness of the first resin layer. Therefore, the transparency of the conductive film is improved while ensuring the adhesion between the first resin layer and the second resin layer.

A display device according to an aspect of the present disclosure includes the conductive film.

According to the display device, the display device with the conductive film having high adhesion between the first resin layer and the second resin layer is obtained.

The present disclosure includes, for example, the following [1] to [8].

[1] A conductive film including:
a base material;
a first resin layer provided on the base material;
a second resin layer provided on the first resin layer and having a trench opening to a surface opposite to the first resin layer; and
a conductive layer provided in the trench,
wherein the first resin layer contains a first resin portion and a plurality of first inorganic particles, and
wherein at least a part of the plurality of first inorganic particles partially protrude from the first resin portion toward the second resin layer.

[2] The conductive film according to [1], wherein the plurality of first inorganic particles are unevenly distributed on a side of the second resin layer in the first resin layer.

[3] The conductive film according to [1] or [2], wherein the second resin layer contains a second resin portion and a plurality of second inorganic particles, and wherein the plurality of second inorganic particles are unevenly distributed on a side of the first resin layer in the second resin layer.

[4] The conductive film according to [3], wherein a plurality of the second inorganic particles are present around a portion protruding toward the second resin layer in each of the plurality of first inorganic particles partially protruding toward the second resin layer.

[5] The conductive film according to [3] or [4], wherein an average particle size of the plurality of second inorganic particles is smaller than an average particle size of the plurality of first inorganic particles.

[6] The conductive film according to any one of [3] to [5], wherein an average particle size of the plurality of second inorganic particles is 10 nm or less.

[7] The conductive film according to any one of [3] to [6], wherein the second inorganic particles corresponding to 80% or more of the total number of the plurality of second inorganic particles are distributed within a region with a distance from a surface of the first resin layer being ⅓ or less of a thickness of the first resin layer.

[8] A display device including:
the conductive film according to any one of [1] to [7].

### EXAMPLES

The present disclosure is not limited to the following examples.

### Example 1

A coating liquid for forming a first resin layer containing silica particles (average particle size: 100 nm), an acrylic resin, and a solvent was prepared. This coating liquid was applied onto a COP film (thickness: 100 μm), and the solvent was removed from the coating on the COP film in a hot air drying oven. Next, the coating was irradiated with ultraviolet light using a UV treatment device to cure the coating, thereby forming a first resin layer having a thickness of 300 μm and containing a first resin portion and silica particles (first inorganic particles) on the COP film.

A coating liquid for forming a second inorganic particle containing layer was prepared, which contained Pd fine particles (average particle diameter: 5 nm), an acrylic resin, and a solvent. This coating liquid was applied onto the first resin layer, and the solvent was removed from the coating on the first resin layer in a hot air drying oven. Next, the coating was irradiated with ultraviolet rays using a UV treatment device to cure the coating, and a second inorganic particle containing layer containing Pd fine particles (second inorganic particles) and having a thickness of 60 μm was formed on the first resin layer, thereby obtaining a laminate.

The laminate after the formation of the second inorganic particle containing layer was placed in a vacuum device, and the surface of the second inorganic particle containing layer was subjected to an ashing process to remove the resin portion in the second inorganic particle containing layer and the resin portion in the surface layer of the first resin layer. The thickness of the first resin layer after the ashing process was 260 μm.

A UV curable resin was applied to the surface of the first resin layer after the ashing process to form a coating having a thickness of 2 μm. Next, a mold having convex portions was pressed into this coating so that the tips of the convex portions of the mold reached the surface of the first resin layer, and in this state the coating was irradiated with ultraviolet light to cure the coating. The mold was removed from the cured coating to form a second resin layer having linear trenches that intersected each other, opened on the surface opposite the first resin layer, and had a mesh-like pattern.

The laminate after the formation of the second resin layer was placed in a vacuum device and subjected to an ashing process to remove the resin constituting the second resin layer remaining at the bottom of the trench.

Next, the laminate was immersed in an electroless plating solution containing nickel sulfate and sodium hypophosphite to grow Ni plating from the surface of the first resin layer and form a Ni layer in the trench.

The laminate on which the Ni layer was formed was immersed in an aqueous solution containing Pd. Next, the laminate after forming the Pd layer was immersed in an electroless plating solution containing copper sulfate and formalin to grow Cu plating on the Ni layer starting from the Pd layer and form a Cu layer in the trench. Accordingly, a conductive layer having a mesh-like pattern including a Ni layer, a Pd layer, and a Cu layer was formed in the trench to form a conductive film.

In order to observe the cross section of the obtained conductive film along the thickness direction, the mesh portion of the conductive film was cut into a plate shape using a focused ion beam (FIB) and subjected to a thin-sectioning process to obtain a sample for TEM observation. The prepared sample was subjected to bright field observation using a TEM (instrument name JEM-2011F) at an accelerating voltage of 200 kV. Then, it was confirmed that some of the plurality of silica particles partially protruded from the first resin portion toward the second resin layer. Furthermore, it was confirmed that the plurality of silica particles were unevenly distributed on the side of the second resin layer in the first resin layer, that the majority (95% or more) of the plurality of Pd fine particles in the second resin layer were distributed within a region separated from the surface of the first resin layer by 50 nm or less, and that a plurality of the Pd fine particles were present around the portion of each silica particle protruding from the first resin portion toward the second resin layer in the TEM observation image.

### Example 2

A conductive film was prepared in the same manner as in Example 1 except that the second inorganic particle containing layer was not formed. When the cross section of the obtained conductive film in the thickness direction was observed by TEM, it was confirmed that a part of the plurality of silica particles partially protrude from the first resin portion toward the second resin layer, that the plurality of silica particles were unevenly distributed on the side of the second resin layer in the first resin layer, that the majority (95% or more) of the plurality of Pd fine particles in the second resin layer were distributed within a region separated from the surface of the first resin layer by 50 nm or less, and that a plurality of the Pd fine particles were present around the portion of each silica particle protruding from the first resin portion toward the second resin layer in the TEM observation image.

### Comparative Example 1

A conductive film was produced in the same manner as in Example 1 except that the ashing process was not performed before the formation of the second resin layer after the second inorganic particle containing layer was formed. When the cross section of the obtained conductive film in the thickness direction was observed by TEM, it was confirmed that the plurality of silica particles were uniformly distributed in the first resin layer and no silica particles partially protrude from the first resin portion toward the second resin layer in the TEM observation image.

### <Evaluation of Adhesion>

Adhesion was evaluated using the cross-cut test specified in JIS K 5600. Specifically, a notch was made with a cutter knife on the surface of the second resin layer to form a right-angled grid pattern (25 squares). Next, a tape was applied onto the grid pattern, the tape was brought into close contact with the surface of the second resin layer, and then the tape was peeled off. After the tape was peeled off, the grid pattern was observed under an optical microscope. If no peeling of the second resin layer was observed, the pattern was rated as A, and if peeling of the second resin layer was observed, the pattern was rated as B.

TABLE 1

| | Ashing process for | Formation of | |
|---|---|---|---|
| | second inorganic | second inorganic | |
| | particle containing | particle containing | |
| | layer | layer | Adhesion |
| Example 1 | Yes | Yes | A |
| Example 1 | Yes | No | A |
| Comparative | No | Yes | B |
| Example 1 | | | |

### REFERENCE SIGNS LIST

1 Base material
10 First resin layer
11, 11a, 11b First inorganic particles
12 First resin portion
20 Second resin layer
21 Second inorganic particles
22 Second resin portion
25 Trench
30 Conductive layer
40 Second inorganic particle containing layer
41 Third resin portion
50 Mold
60 Image display unit
70 Polarizing plate
80 Cover glass
100 Conductive film
500 Display device

1. A conductive film comprising:
a base material;
a first resin layer provided on the base material;
a second resin layer provided on the first resin layer and having a trench opening to a surface opposite to the first resin layer; and
a conductive layer provided in the trench,
wherein the first resin layer comprises a first resin portion and a plurality of first inorganic particles, and
wherein at least a part of the plurality of first inorganic particles partially protrude from the first resin portion toward the second resin layer.

2. The conductive film according to claim 1,
wherein the plurality of first inorganic particles are unevenly distributed on a side of the second resin layer in the first resin layer.

3. The conductive film according to claim 1,
wherein the second resin layer comprises a second resin portion and a plurality of second inorganic particles, and
wherein the plurality of second inorganic particles are unevenly distributed on a side of the first resin layer in the second resin layer.

4. The conductive film according to claim 3,
wherein a plurality of the second inorganic particles are present around a portion protruding toward the second resin layer in each of the plurality of first inorganic particles partially protruding toward the second resin layer.

5. The conductive film according to claim 3,
wherein an average particle size of the plurality of second inorganic particles is smaller than an average particle size of the plurality of first inorganic particles.

6. The conductive film according to claim 3,
wherein an average particle size of the plurality of second inorganic particles is 10 nm or less.

7. The conductive film according to claim 3,
wherein 80% or more of the total number of the second inorganic particles are distributed within a region with a distance from a surface of the first resin layer being ⅓ or less of a thickness of the first resin layer.

8. A display device comprising:
the conductive film according to claim 1.
